(19) United States
(12) Patent Application Publication
(10) Pub. No.: US 2025/0357436 A1
(43) Pub. Date: Nov. 20, 2025

(54) PIXEL STRUCTURE

(71) Applicant: AUO Corporation, Hsinchu City (TW)

(72) Inventors: Zhi-Jian Yu, Hsinchu City (TW); Han-Chung Lai, Hsinchu City (TW); Han-Hung Kuo, Hsinchu City (TW); Kuan-Lin Chiu, Hsinchu City (TW)

(73) Assignee: AUO Corporation, Hsinchu City (TW)

(21) Appl. No.: 18/798,714

(22) Filed: Aug. 8, 2024

(30) Foreign Application Priority Data
May 15, 2024 (TW) 113117830

(51) Int. Cl. H01L 25/075; H01L 33/62

(52) U.S. Cl. CPC H01L 25/0753; H10H 20/857

(57) ABSTRACT

A pixel structure includes a common electrode and sub-pixel structures. The common electrode includes a first common electrode portion and a second common electrode portion that cross each other. Each of the sub-pixel structures includes a pad group and a light-emitting element. The pad group at least includes a first pad. The light-emitting element is bonded to the pad group. The sub-pixel structures include a first sub-pixel structure, a second sub-pixel structure and a third sub-pixel structure. In a top view of the pixel structure, the pad group of the first sub-pixel structure and the pad group of the second sub-pixel structure are separated by the first common electrode portion, and the pad group of the second sub-pixel structure and the pad group of the third sub-pixel structure are separated by the second common electrode portion. In addition, another pixel structure is also provided.

### CROSS-REFERENCE TO RELATED APPLICATION

This application claims the priority benefit of Taiwan application serial no. 113117830, filed on May 15, 2024. The entirety of the above-mentioned patent application is hereby incorporated by reference herein and made a part of this specification.

### BACKGROUND

### Technical Field

The disclosure relates to a pixel structure.

### Description of Related Art

A light-emitting diode display panel includes a driving backplane and a plurality of light-emitting diode elements transferred onto the driving backplane. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation.

Generally speaking, in the manufacturing process of the light-emitting diode display panel, a laser bonding technology can be used to melt the solder so that electrodes of the light-emitting diode element are bonded to the pad groups of the driving backplane. During the above-mentioned laser bonding process, there is a temperature difference between the pad groups of the pixel structures. When the temperature difference is too large, the light-emitting diode elements are prone to problems such as position deviation, rotation, and falling off, which affects the yield of the light-emitting diode display panel.

### SUMMARY

This disclosure provides a pixel structure that helps improve bonding yield.

The pixel structure of an embodiment of this disclosure comprises a common electrode and sub-pixel structures. The common electrode comprises a first common electrode portion and a second common electrode portion crossing each other. Each of the sub-pixel structures comprises a pad group and a light-emitting element. The pad group at least comprises a first pad. The light-emitting element is bonded to the pad group. The sub-pixel structures comprises a first sub-pixel structure, a second sub-pixel structure and a third sub-pixel structure. In a top view of the pixel structure, the pad group of the first sub-pixel structure and the pad group of the second sub-pixel structure are separated by the first common electrode portion, and the pad group of the second sub-pixel structure and the pad group of the third sub-pixel structure are separated by the second common electrode portion.

The pixel structure of another embodiment of this disclosure comprises a common electrode and sub-pixel structures. The common electrode comprises a conductive portion, wherein the conductive portion comprises a first sub-portion and a second sub-portion outside the first sub-portion. Each of the sub-pixel structures comprises a pad group and a light-emitting element. The pad group at least comprises a first pad. The light-emitting element is bonded to the pad group. The sub-pixel structures comprise a first sub-pixel structure, a second sub-pixel structure and a third sub-pixel structure respectively arranged in a straight direction. In a top view of the pixel structure, the pad group of the first sub-pixel structure and the pad group of the second sub-pixel structure are separated by the first sub-portion of the conductive portion of the common electrode, and the pad group of the second sub-pixel structure and the pad group of the third sub-pixel structure are separated by the second sub-portion of the conductive portion of the common electrode.

### BRIEF DESCRIPTION OF THE DRAWINGS

FIG. 1 is a schematic top view of a display panel according to an embodiment of the present disclosure.

FIG. 2 is a schematic top view of the pixel structure of the display panel according to an embodiment of the present disclosure.

FIG. 3 is a schematic cross-sectional view of a display panel according to an embodiment of the present disclosure.

FIG. 4 is a schematic cross-sectional view of a display panel according to an embodiment of the present disclosure.

FIG. 5 is a schematic top view of the pixel structure of the display panel of a comparative example.

FIG. 6 is a schematic top view of the pixel structure of the display panel according to another embodiment of the present disclosure.

FIG. 7 is a schematic top view of the pixel structure of the display panel according to another embodiment of the present disclosure.

FIG. 8 is a schematic top view of the pixel structure of the display panel according to yet another embodiment of the present disclosure.

FIG. 9 is a schematic top view of the pixel structure of the display panel according to an embodiment of the present disclosure.

FIG. 10 is a schematic top view of the pixel structure of a display panel according to another embodiment of the present disclosure.

FIG. 11 is a schematic top view of the pixel structure of the display panel according to another embodiment of the present disclosure.

FIG. 12 is a schematic top view of the pixel structure of the display panel according to yet another embodiment of the present disclosure.

FIG. 13 is a schematic top view of the pixel structure of the display panel according to one embodiment of the present disclosure.

FIG. 14 is a schematic top view of the pixel structure of a display panel according to another embodiment of the present disclosure.

FIG. 15 is a schematic top view of the pixel structure of the display panel according to another embodiment of the present disclosure.

FIG. 16 is a schematic top view of the pixel structure of the display panel according to yet another embodiment of the present disclosure.

FIG. 17 is a schematic top view of the pixel structure of the display panel according to one embodiment of the present disclosure.

FIG. 18 is a schematic top view of the pixel structure of the display panel according to another embodiment of the present disclosure.

FIG. 19 is a schematic top view of the pixel structure of the display panel according to another embodiment of the present disclosure.

FIG. 20 is a schematic top view of the pixel structure of the display panel according to yet another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

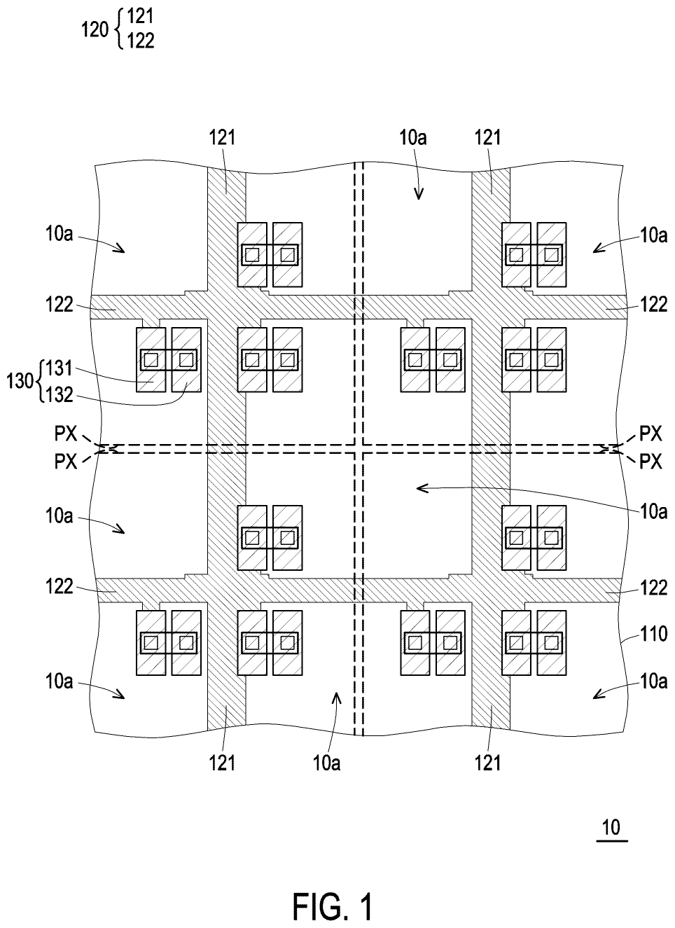

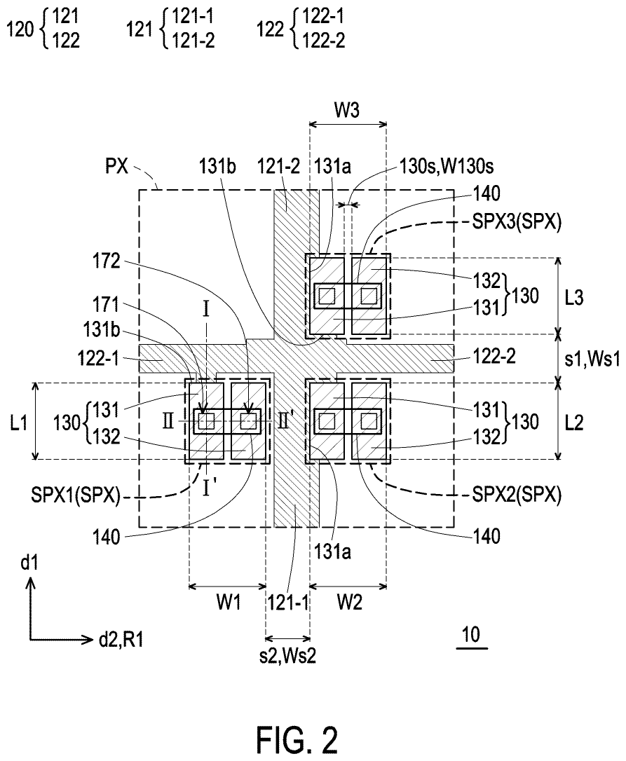

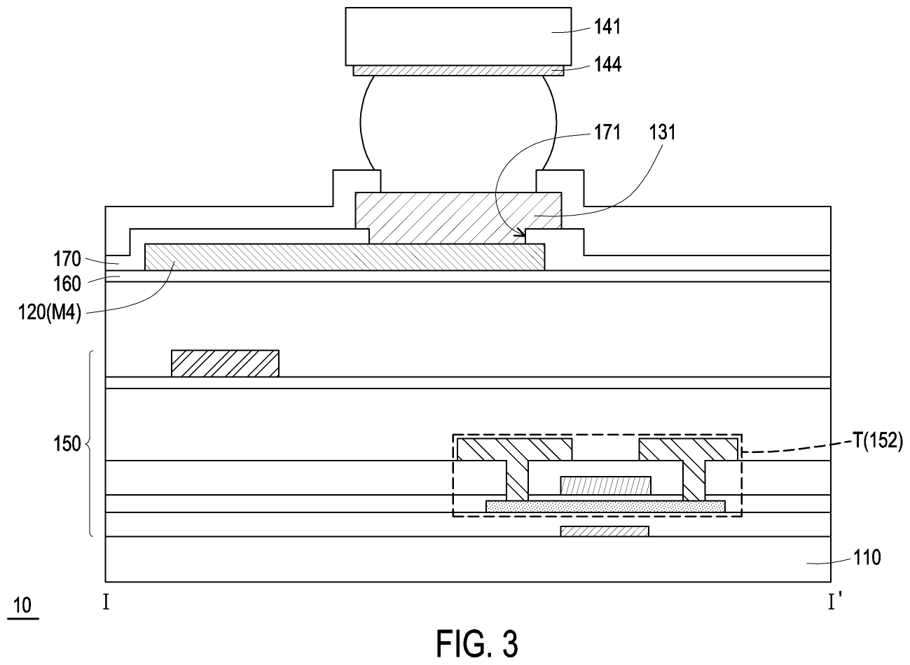

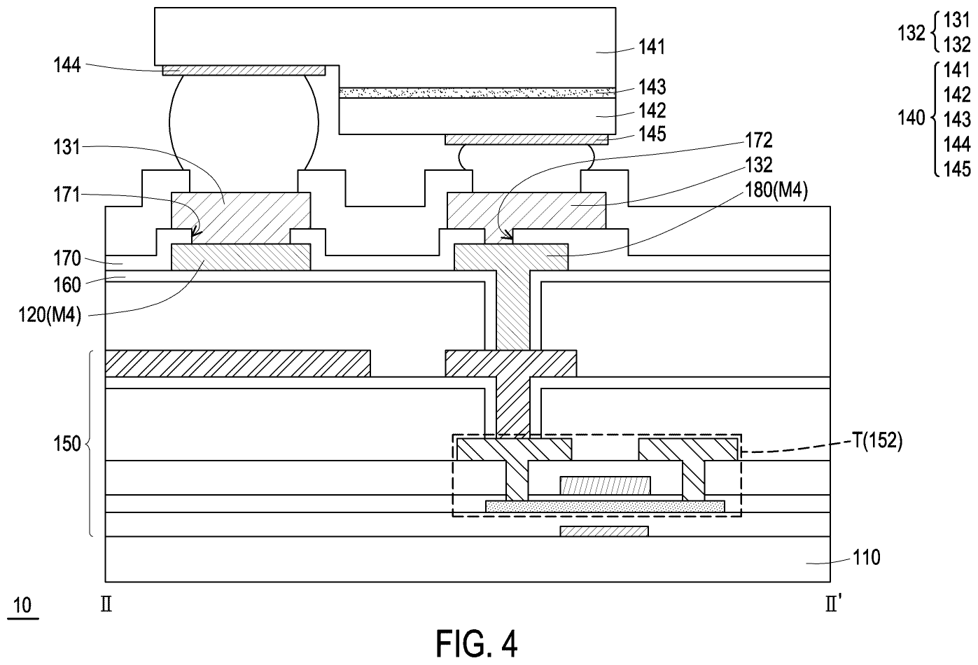

FIG. 1 is a schematic top view of a display panel according to an embodiment of the present disclosure. FIG. 2 is a schematic top view of the pixel structure of the display panel according to an embodiment of the present disclosure. FIG. 3 is a schematic cross-sectional view of a display panel according to an embodiment of the present disclosure. FIG. 3 corresponds to the line segment I-I′ in FIG. 2. FIG. 4 is a schematic cross-sectional view of a display panel according to an embodiment of the present disclosure. FIG. 4 corresponds to the line segment II-II′ in FIG. 2.

Referring to FIG. 1 and FIG. 2, the display panel 10 includes a substrate 110 and pixel structures PX disposed on the substrate 110. For example, in some embodiments, the material of the substrate 110 may be glass, quartz, organic polymer, or other applicable materials.

Referring to FIG. 2, the pixel structure PX includes a common electrode 120 and sub-pixel structures SPX. Each of the sub-pixel structures SPX includes a pad group 130 and a light-emitting element 140, wherein the pad group 130 at least includes a first pad 131, and the light-emitting element 140 is bonded to the pad group 130. In some embodiments, the pad group 130 of each of the sub-pixel structures SPX may optionally further include a second pad 132, wherein the second pad 132 and the first pad 131 are structurally separated from each other. In some embodiments, the number of pads of one pad group 130 may be two. However, this disclosure is not limited to thereto. In other embodiments, the number of pads of one pad group 130 may also be 1, or a positive integer greater than or equal to 3.

Referring to FIG. 2, FIG. 3 and FIG. 4, in some embodiments, the light-emitting element 140 includes a first-type semiconductor layer 141, a second-type semiconductor layer 142, an active layer 143 disposed between the first-type semiconductor layer 141 and the second-type semiconductor layer, a first electrode 144 electrically connected to the first-type semiconductor layer 141 and the second electrode 145 electrically connected to the second-type semiconductor layer 142, wherein at least one of the first electrode 144 and the second electrode 145 of the light-emitting element 140 is bonded to a corresponding pad group 130. For example, in some embodiments, the light-emitting element 140 may be a micro light-emitting diode (μLED). However, this disclosure is not limited thereto. In other embodiments, the light-emitting element 140 may also be a light-emitting element with other sizes and/or types.

Referring to FIG. 2 and FIG. 4, in some embodiments, the first electrode 144 and the second electrode 145 of the light-emitting element 140 are located on the same side of the active layer 143. The light-emitting element 140 may be a flip-chip type light-emitting element, and the first electrode 144 and the second electrode 145 of the light-emitting element 140 may be respectively bonded to the first pad 131 and the second pad 132 of a corresponding pad group 130. However, this disclosure is not limited thereto, in other embodiments, the light-emitting element 140 may also be other types. For example, in some embodiments, the first electrode 144 and the second electrode 145 of the light-emitting element 140 may be located on opposite sides of the active layer 143 respectively, and the light-emitting element 140 may be a vertical type light-emitting element, and one of the first electrode 144 and the second electrode 145 of the light-emitting element 140 is bonded to the first pad 131 of the corresponding pad group 130.

Referring to FIG. 2, in some embodiments, the sub-pixel structures SPX of the pixel structure PX includes a first sub-pixel structure SPX1, a second sub-pixel structure SPX2 and a third sub-pixel structure SPX3, and the light-emitting element 140 of the first sub-pixel structure SPX1, the light-emitting element 140 of the second sub-pixel structure SPX2 and the light-emitting element 140 of the third sub-pixel structure SPX3 are respectively used to emit a first color light, a second color light and a third color light that are different with each other. For example, in some embodiments, the first color light, the second color light and the third color light may include red light, green light and blue light, but this disclosure is not limited to thereto.

Referring to FIG. 2 and FIG. 4, in some embodiments, the display panel 10 further includes a driving circuit structure 150 disposed on the substrate 110. The driving circuit structure 150 includes sub-pixel driving circuits 152, and the sub-pixel driving circuits 152 are electrically connected to pad groups 130 respectively. For example, in some embodiments, a sub-pixel driving circuit 152 may include a thin film transistor T, a first pad 131 of a pad group 130 may be electrically connected to the common electrode 120, and a second pad 132 of the pad group 130 may be electrically connected to the thin film transistor T.

Referring to FIG. 2, FIG. 3 and FIG. 4, in some embodiments, the display panel 10 may further include a first insulating layer 160, the driving circuit structure 150 is disposed on the substrate 110, the first insulating layer 160 is disposed on the driving circuit structure 150, the common electrode 120 is disposed on the first insulating layer 160, and the pad group 130 is disposed on a conductive layer M4 to which the common electrode 120 belongs. In some embodiments, the display panel 10 may further include a second insulating layer 170 disposed on the conductive layer M4 to which the common electrode 120 belongs, and the pad group 130 may be disposed on the second insulating layer 170, the conductive layer M4 further includes a bridge electrode 180 that is structurally separated from the common electrode 120, the bridge electrode 180 is electrically connected to the thin film transistor T, the first pad 131 and the second pad 132 of the pad group 130 may be electrically connected to the common electrode 120 and the bridge electrode 180 respectively through contact windows 171 and 172 of the second insulation layer 170. However, this disclosure is not limited to thereto, in other embodiments, the display panel 10 may not include the second insulating layer 170, and the first pad 131 and the second pad 132 of the pad group 130 may also be directly formed on at least a portion of the common electrode 120 and at least a portion of the bridge electrode 180.

In some embodiments, the conductive layer M4 to which the common electrode 120 belongs is generally made of metal material. However, this disclosure is not limited to thereto. According to other embodiments, the conductive layer M4 may use other conductive materials, such as alloys, nitrides of metal materials, oxides of metal materials, oxynitrides of metal materials, or a stack of metal materials and other conductive materials. In some embodiments, the material of the pad group 130 may include gold (Au), nickel-gold (NiAu) alloy, or combinations thereof, but this disclosure is not limited to thereto.

Referring to FIG. 2, the pixel structure PX includes a common electrode 120, wherein the common electrode 120 includes a first common electrode portion 121 and a second common electrode portion 122 that intersect with each other. Referring FIG. 1 and FIG. 2, in some embodiments, the pixel structures PX may be arranged into multiple rows and multiple columns, wherein first common electrode portions 121 of common electrodes 120 of pixel structures PX of the same column may be connected in series with each other, and second common electrode portions 122 of common electrodes 120 of pixel structures PX of the same row may be connected in series with each other, transparent areas 10a are surrounded by the common electrodes 120 of the pixel structures PX and are not occupied by the pad groups 130. In some embodiments, the display panel 10 may optionally be a transparent display panel having the transparent areas 10a. However, this disclosure is not limited to thereto. In other embodiments, the display panel 10 may be a non-transparent display panel.

Referring to FIG. 2, it is worth noting that the sub-pixel structures SPX of the pixel structure PX include a first sub-pixel structure SPX1, a second sub-pixel structure SPX2 and a third sub-pixel structure SPX3. In a top view of the pixel structure PX, the pad group 130 of the first sub-pixel structure SPX1 and the pad group 130 of the second sub-pixel structure SPX2 are separated by the first common electrode portion 121, and the pad group 130 of the second sub-pixel structure SPX2 and the pad group 130 of the third sub-pixel structure SPX3 are separated by the second common electrode portion 122.

Thereby, the pad group 130 of the first sub-pixel structure SPX1, the pad group 130 of the second sub-pixel structure SPX2, and the pad group 130 of the third sub-pixel structure SPX3 can be arranged in the same or similar position relative to the common electrode 120. In this way, when the light-emitting elements 140 and the pad groups 130 are bonded by using the laser bonding process, the temperatures of the pad groups 130 of the first sub-pixel structure SPX1, the second sub-pixel structure SPX2 and the third sub-pixel structure SPX3 can be similar, thereby improving the problem of poor bonding caused by the temperature difference of the multiple pad groups 130 (for example: a position deviation of a light-emitting element 140, a rotation of a light-emitting element 140, a falling off of a light-emitting element 140, etc.)

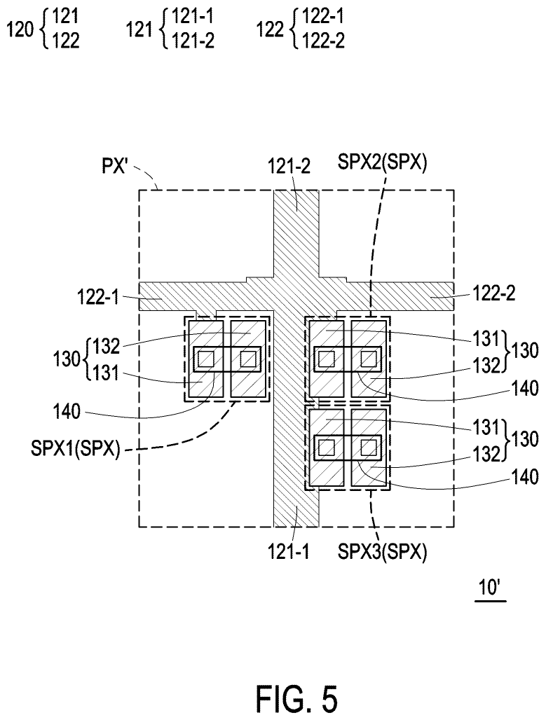

FIG. 5 is a schematic top view of the pixel structure of the display panel of a comparative example. The pixel structure PX′ of the display panel 10′ of the comparative example in FIG. 5 is similar to the pixel structure PX of the display panel 10 of the embodiment of FIG. 2. The main difference between the two is: in the comparative example, the pad group 130 of the second sub-pixel structure SPX2 of the pixel structure PX′ and the pad group 130 of the third sub-pixel structure SPX3 are not separated by the common electrode 120. In the comparative example of FIG. 5, when performing a laser bonding process to bond multiple light-emitting elements 140 and multiple pad groups 130, a maximum temperature difference of the multiple pad groups 130 of the first sub-pixel structure SPX1, the second sub-pixel structure SPX2 and the third sub-pixel structure SPX3 of the pixel structure PX′ can reach, for example, 7° C. In the embodiment of FIG. 2, when performing a laser bonding process to bond multiple light-emitting elements 140 and multiple pad groups 130, a maximum temperature difference of the multiple pad groups 130 of the first sub-pixel structure SPX1, the second sub-pixel structure SPX2 and the third sub-pixel structure SPX3 of the pixel structure PX can be reduced to, for example, 3° C. This data shows that by separating the multiple pad groups 130 of the first sub-pixel structure SPX1, the second sub-pixel structure SPX2 and the third sub-pixel structure SPX3 through the common electrode 120, it can indeed reduce the temperature difference between the multiple pad groups 130 of the first sub-pixel structure SPX1, the second sub-pixel structure SPX2 and the third sub-pixel structure SPX3 during the laser bonding process, thereby improving the yield rate.

Referring to FIG. 2, in some embodiments, one pixel structure PX includes three pad groups 130 as an example. However, this disclosure is not limited to thereto. In other embodiments, one pixel structure PX may include four or more than four pad groups 130.

Referring to FIG. 2, the first direction d1 is substantially parallel to the first common electrode portion 121, the second direction d2 is substantially parallel to the second common electrode portion 122, and the pad group 130 of each of the sub-pixel structures SPX is adjacent to the first common electrode portion 121 and has a first size L1/L2/L3 in the first direction d1, and the pad group 130 of each of the sub-pixel structures SPX is adjacent to the second common electrode portion 122 and has a second size W1/W2/W3 in the second direction d2. It should be noted that if a pad group 130 includes 2 or more pads, the first size L1/L2/L3 of the pad group 130 of each of the sub-pixel structures SPX in the first direction d1 refer to the size of a pad closer to the first common electrode portion 121 of the pad group 130 in the first direction d1; if a pad group 130 includes 2 or more pads, the second size W1/W2/W3 of the pad group 130 of each of the sub-pixel structures SPX in the second direction d2 refer to the sum of the widths of the pads of the pad group 130 in the second direction d2 and the width W130s of the gap 130s between the pads.

In some embodiments, the ratio [(L1+W1)/(L2+W2)] of the sum (L1+W1) of the first size L1 and the second size W1 of the first sub-pixel structure SPX1 to the sum (L2+W2) of the first size L2 and the second size W2 of the second sub-pixel structure SPX2 can be greater than 0.8 and less than 1.2. That is to say, the arrangement of the pad group 130 of the first sub-pixel structure SPX1 relative to the common electrode 120 is the same or similar to the arrangement of the pad group 130 of the second sub-pixel structure SPX2 relative to the common electrode 120.

In some embodiments, the ratio [(L1 +W1)/(L3+W3)] of the sum (L1+W1) of the first size L1 and the second size W1 of the first sub-pixel structure SPX1 to the sum (L3+W3) of the first size L3 and the second size W3 of the third sub-pixel structure SPX3 can be greater than 0.8 and less than 1.2. That is to say, the arrangement of the pad group 130 of the first sub-pixel structure SPX1 relative to the common electrode 120 is the same or similar to the arrangement of the pad group 130 of the third sub-pixel structure SPX3 relative to the common electrode 120.

In some embodiments, the ratio [(L2+W2)/(L3+W3)] of the sum (L2+W2) of the first size L2 and the second size W2 of the second sub-pixel structure SPX2 to the sum (L3+W3) of the first size L3 and the second size W3 of the third sub-pixel structure SPX3 can be greater than 0.8 and less than 1.2. That is to say, the arrangement of the pad group 130 of the second sub-pixel structure SPX2 relative to the common electrode 120 is the same or similar to the arrangement of the pad group 130 of the third sub-pixel structure SPX3 relative to the common electrode 120.

Referring to FIG. 2, the first common electrode portion 121 includes a first sub-portion 121-1 and a second sub-portion 121-2 respectively located on opposite sides of the second common electrode portion 122. The second common electrode portion 122 includes a first sub-portion 122-1 and a second sub-portion 122-2 respectively located on opposite sides of the first common electrode portion 121. In some embodiments, the first pad 131 of the second sub-pixel structure SPX2 has a long side 131a and a short side 131b adjacent to each other; in the top view of the pixel structure PX, the long side 131a of the first pad 131 of the second sub-pixel structure SPX2 is adjacent to the first sub-portion 121-1 of the first common electrode portion 121, and the second pad 132 of the second sub-pixel structure SPX2 and the common electrode 120 are separated by the first pad 131 of the second sub-pixel structure SPX2; the first pad 131 of the third sub-pixel structure SPX3 has long side 131a and short side 131b adjacent to each other; in the top view of the pixel structure PX, the long side 131a of the first pad 131 of the third sub-pixel structure SPX3 is adjacent to the second sub-portion 121-2 of the first common electrode portion 121, and the second pad 132 of the third sub-pixel structure SPX3 and the common electrode 120 are separated by the first pad 131 of the third sub-pixel structure SPX3.

Referring to FIG. 2, in some embodiments, in the top view of the pixel structure PX, the short side 131b of the first pad 131 of the first sub-pixel structure SPX1 is adjacent to the first sub-portion 122-1 of the second common electrode portion 122, and the short side 131b of the first pad 131 of the third sub-pixel structure SPX3 is adjacent to the second sub-portion 122-2 of the second common electrode portion 122.

Referring to FIG. 2, in some embodiments, there is a gap s1 between the pad group 130 of the second sub-pixel structure SPX2 and the pad group 130 of the third sub-pixel structure SPX3, and the width Ws1 of the gap s1 in the first direction d1 may be greater than or equal to 5 μm. In some embodiments, there is a gap s2 between the pad group 130 of the first sub-pixel structure SPX1 and the pad group 130 of the second sub-pixel structure SPX2, and the width Ws2 of the gap s2 in the second direction d2 may be greater than or equal to 5 μm.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

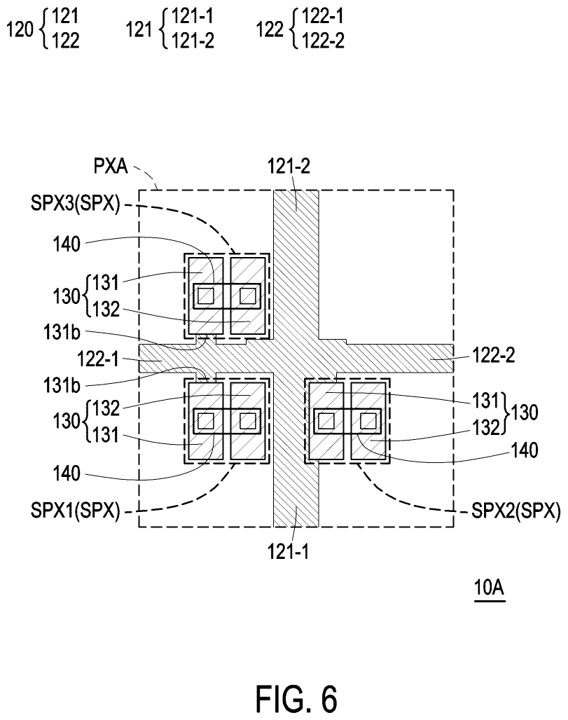

FIG. 6 is a schematic top view of the pixel structure of the display panel according to another embodiment of the present disclosure. The pixel structure PXA of the display panel 10A of FIG. 6 is similar to the pixel structure PX of the display panel 10 of FIG. 2. The difference between the two is that the positions of the pad groups 130 of the third sub-pixel structures SPX3 of the two pixel structures PX and PXA are different. Specifically, in the embodiment of FIG. 6, in the top view of the pixel structure PXA, the short side 131b of the first pad 131 of the first sub-pixel structure SPX1 is adjacent to the first sub-portion 122-1 of the second common electrode portion 122, and the short side 131b of the first pad 131 of the third sub-pixel structure SPX3 is also adjacent to the first sub-portion 122-1 of the second common electrode portion 122. In the embodiment of FIG. 6, in the top view of the pixel structure PXA, the pad group 130 of the first sub-pixel structure SPX1 and the pad group 130 of the third sub-pixel structure SPX3 are located on the same side of the first common electrode portion 121. In addition, in the embodiment of FIG. 6, in the top view of the pixel structure PXA, the second pad 132 of the third sub-pixel structure SPX3 is disposed between the first pad 131 of the third sub-pixel structure SPX3 and the second sub-portion 121 of the first common electrode portion 121.

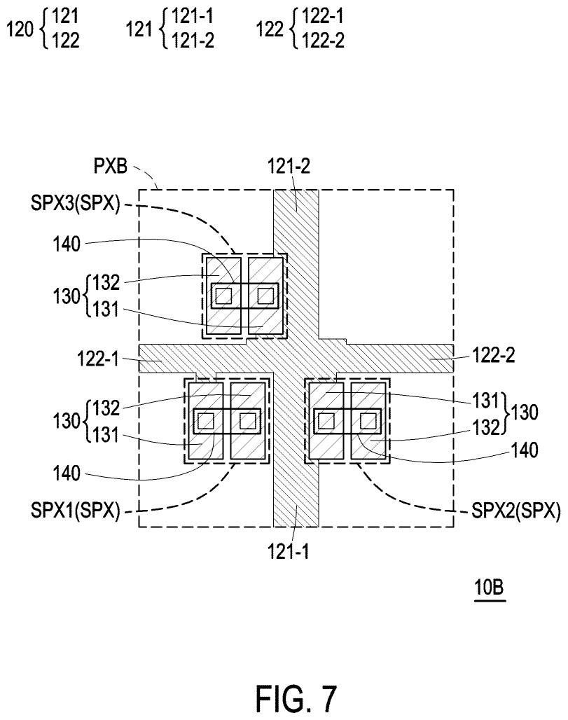

FIG. 7 is a schematic top view of the pixel structure of the display panel according to another embodiment of the present disclosure. The pixel structure PXB of the display panel 10B in FIG. 7 is similar to the pixel structure PXA of the display panel 10A in FIG. 6. The difference between the two is: in the embodiment of FIG. 7, in the top view of the pixel structure PXB, the first pad 131 of the third sub-pixel structure SPX3 is disposed between the second pad 132 of the third sub-pixel structure SPX3 and the second sub-portion 121-2 of the first common electrode portion 121.

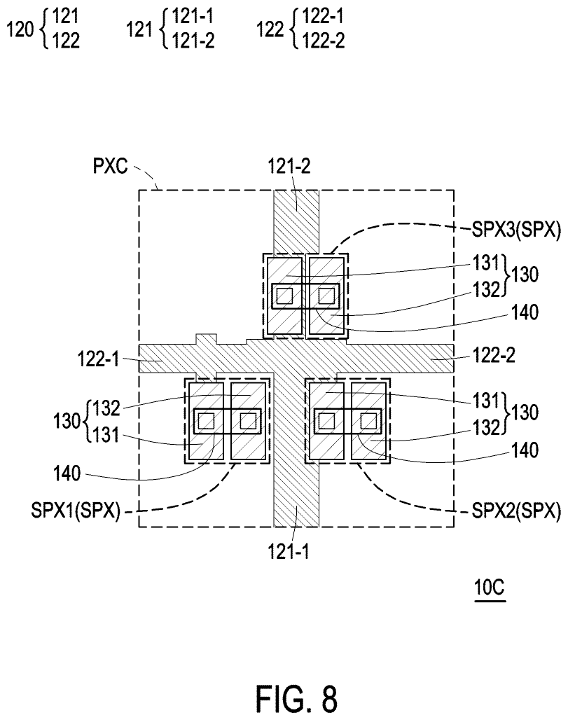

FIG. 8 is a schematic top view of the pixel structure of the display panel according to yet another embodiment of the present disclosure. The pixel structure PXC of the display panel 10C in FIG. 8 is similar to the pixel structure PX of the display panel 10 in FIG. 2. The difference between the two is: in the embodiment of FIG. 8, in the top view of the pixel structure PXC, the first pad 131 and the second pad 132 of the pad group 130 of the third sub-pixel structure SPX3 are respectively located on opposite sides of the second sub-portion 121-2 of the first common electrode portion 121.

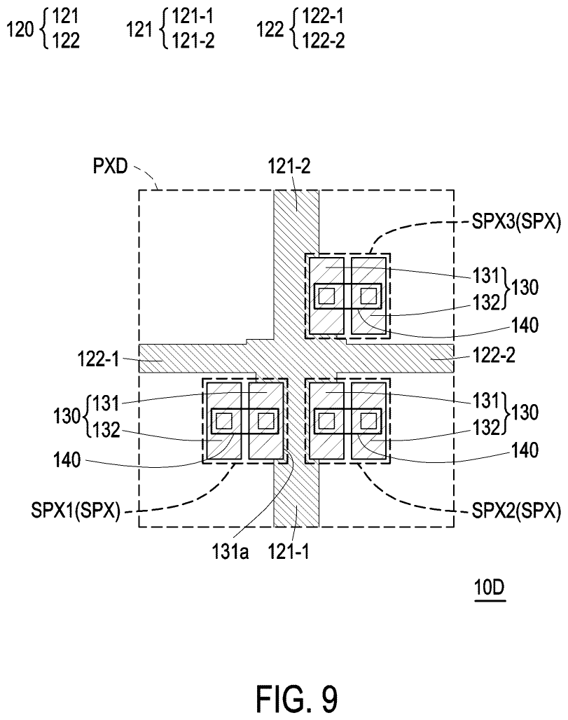

FIG. 9 is a schematic top view of the pixel structure of the display panel according to an embodiment of the present disclosure. The pixel structure PXD of the display panel 10D in FIG. 9 is similar to the pixel structure PX of the display panel 10 in FIG. 2. The difference between the two is: in the embodiment of FIG. 9, in the top view of the pixel structure PXD, the long side 131a of the first pad 131 of the first sub-pixel structure SPX1 is adjacent to the first sub-portion 121-1 of the first common electrode portion 121, and the second pad 132 of the first sub-pixel structure SPX1 and the first common electrode portion 121 are separated by the first pad 131 of the first sub-pixel structure SPX1.

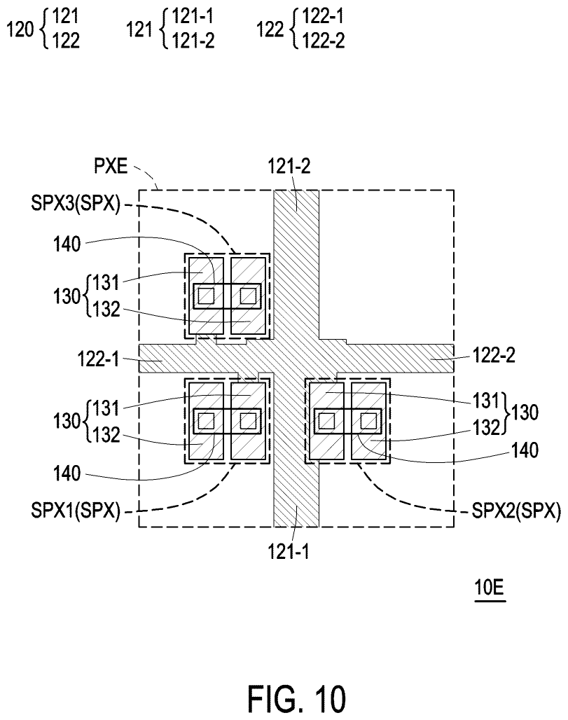

FIG. 10 is a schematic top view of the pixel structure of a display panel according to another embodiment of the present disclosure. The pixel structure PXE of the display panel 10E in FIG. 10 is similar to the pixel structure PXD of the display panel 10D in FIG. 9. The difference between the two is: in the embodiment of FIG. 10, in the top view of the pixel structure PXE, the pad group 130 of the first sub-pixel structure SPX1 and the pad group 130 of the third sub-pixel structure SPX3 are located on the same side of the first common electrode portion 121, and the second pad 132 of the third sub-pixel structure SPX3 is located between the first pad 131 of the third sub-pixel structure SPX3 and the first common electrode portion 121.

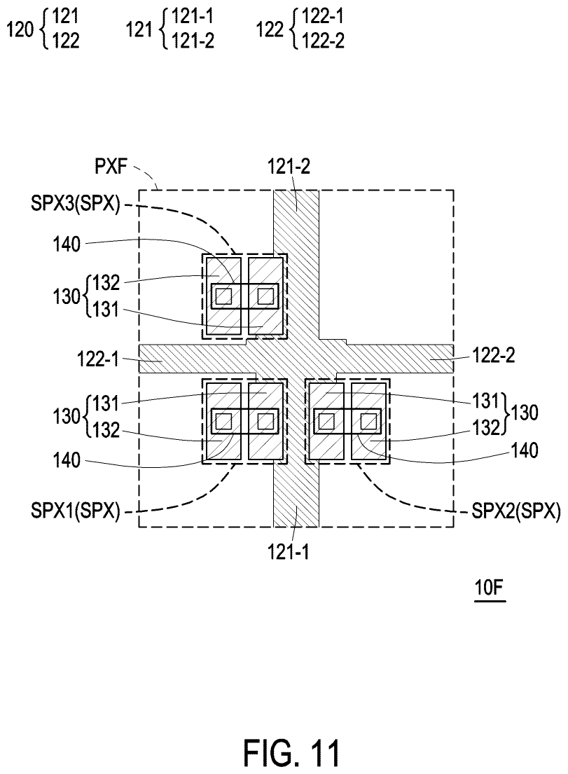

FIG. 11 is a schematic top view of the pixel structure of the display panel according to another embodiment of the present disclosure. The pixel structure PXF of the display panel 10F in FIG. 11 is similar to the pixel structure PXD of the display panel 10D in FIG. 9. The difference between the two is: in the embodiment of FIG. 11, in the top view of the pixel structure PXF, the pad group 130 of the third sub-pixel structure SPX3 and the pad group 130 of the first sub-pixel structure SPX1 are located on the same side of the first common electrode portion 121.

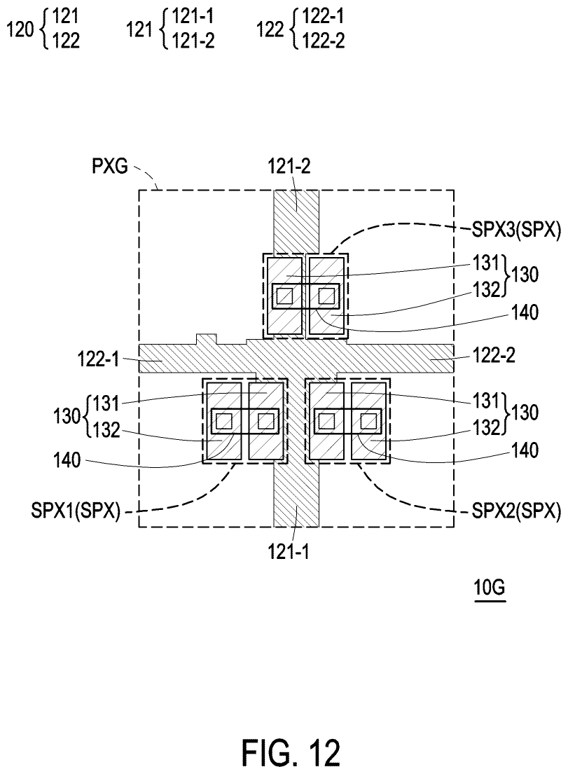

FIG. 12 is a schematic top view of the pixel structure of the display panel according to yet another embodiment of the present disclosure. The pixel structure PXG of the display panel 10G in FIG. 12 is similar to the pixel structure PXD of the display panel 10D in FIG. 9. The difference between the two is: in the embodiment of FIG. 12, in the top view of the pixel structure PXG, the first pad 131 and the second pad 132 of the third sub-pixel structure SPX3 are located on opposite sides of the first common electrode portion 121.

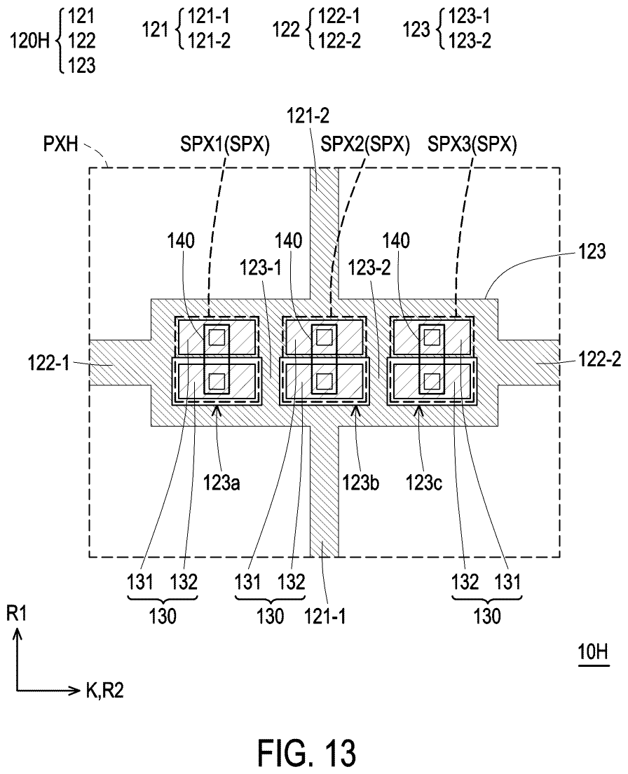

FIG. 13 is a schematic top view of the pixel structure of the display panel according to one embodiment of the present disclosure. Referring to FIG. 13, the pixel structure PXH of the display panel 10H includes a common electrode 120H and sub-pixel structures SPX. Each of the sub-pixel structures SPX includes a pad group 130 and a light-emitting element 140 bonded to the pad group 130, wherein the pad group 130 at least includes a first pad 131, and the first pad 131 is electrically connected to the common electrode 120H. The common electrode 120H includes a conductive portion 123, and the conductive portion 123 includes a first sub-portion 123-1 and a second sub-portion 123-2 outside the first sub-portion 123-1. In some embodiments, the conductive portion 123 of the common electrode 120H may be disposed at the intersection of the first common electrode portion 121 and the second common electrode portion 122.

It is worth noting that the sub-pixel structures SPX include a first sub-pixel structure SPX1, a second sub-pixel structure SPX2 and a third sub-pixel structure SPX3 respectively arranged in the straight direction K. In the top view of the pixel structure PXH, the pad group 130 of the first sub-pixel structure SPX1 and the pad group 130 of the second sub-pixel structure SPX2 are separated by the first sub-portion 123-1 of the conductive portion 123 of the common electrode 120, and the pad group 130 of the second sub-pixel structure SPX2 and the pad group 130 of the third sub-pixel structure SPX3 are separated by the second sub-portion 123-2 of the conductive portion 123 of the common electrode 120H.

In some embodiments, the conductive portion 123 of the common electrode 120H has a first opening 123a, a second opening 123b and a third opening 123c, the first sub-portion 123-1 of the conductive portion 123 is located between the first opening 123a and the second opening 123b, and the second sub-portion 123-2 of the conductive portion 123 is located between the second opening 123b and the third opening 123c; in the top view of the pixel structure PXH, the second pad 132 of the first sub-pixel structure SPX1, the second pad 132 of the second sub-pixel structure SPX2 and the second pad 132 of the third sub-pixel structure SPX3 are respectively located in the first opening 123a, the second opening 123b and the third opening 123c.

In some embodiments, the arrangement direction R1 of the first pad 131 and the second pad 132 of the pad group 130 of each of the sub-pixel structures SPX is staggered with the arrangement direction R2 of the first opening 123a, the second opening 123b and the third opening 123c. For example, in some embodiments, the arrangement direction R1 of the first pad 131 and the second pad 132 of the pad group 130 of each of the sub-pixel structures SPX may be perpendicular to the arrangement direction R2 of the first opening 123a, the second opening 123b and the third opening 123c, but this disclosure does not limited to thereto.

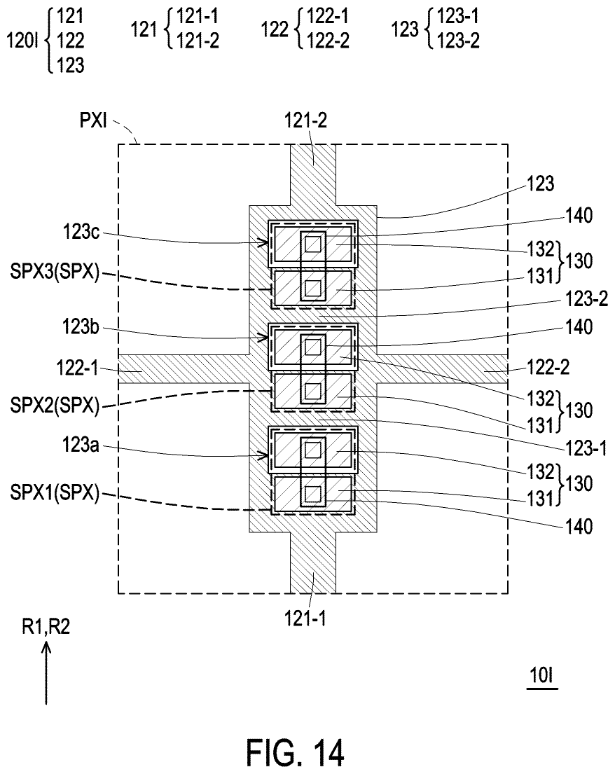

FIG. 14 is a schematic top view of the pixel structure of a display panel according to another embodiment of the present disclosure. The pixel structure PXI of the display panel 101 of FIG. 14 is similar to the pixel structure PXH of the display panel 10H of FIG. 13. The common electrode 120I of FIG. 14 also includes a first common electrode portion 121, a second common electrode portion 122 and a conductive portion 123. The difference between the two is: in the embodiment of FIG. 14, the arrangement direction R1 of the first pad 131 and the second pad 132 of each of the sub-pixel structures SPX is consistent with the arrangement direction R2 of the first opening 123a, the second opening 123b and the third opening 123c.

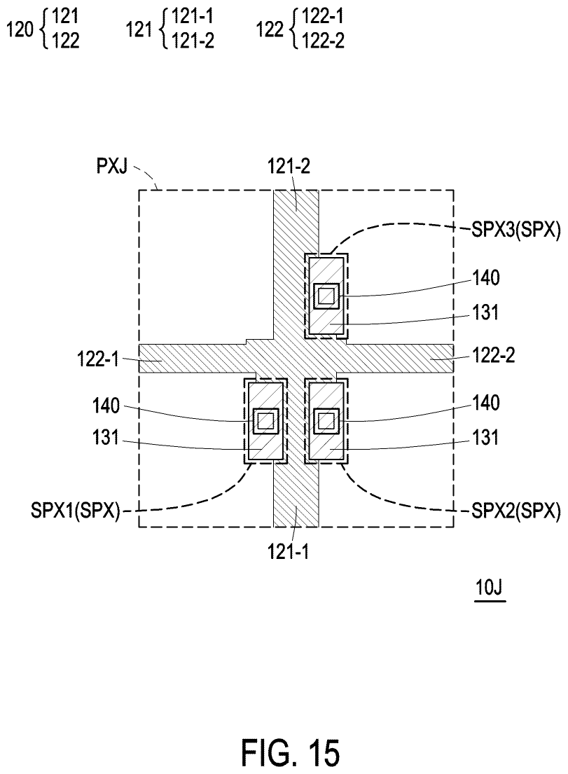

FIG. 15 is a schematic top view of the pixel structure of the display panel according to another embodiment of the present disclosure. The pixel structure PXJ of the display panel 10J of FIG. 15 is similar to the pixel structure PXD of the display panel 10D of FIG. 9. The difference between the two is: in the embodiment of FIG. 15, the pad group 130 of each sub-pixel structure SPX includes the first pad 131 but may not include the second pad 132 of FIG. 9. In addition, in the embodiment of FIG. 15, the light-emitting element 140 of each of the sub-pixel structure SPX may be a vertical type light-emitting element, the first electrode (not shown) and the second electrodes (not shown) of the vertical type light-emitting element may be respectively located on opposite sides of the active layer (not shown) of the vertical light-emitting element, wherein the first electrode of the vertical light-emitting element may be electrically connected to the corresponding first pad 131.

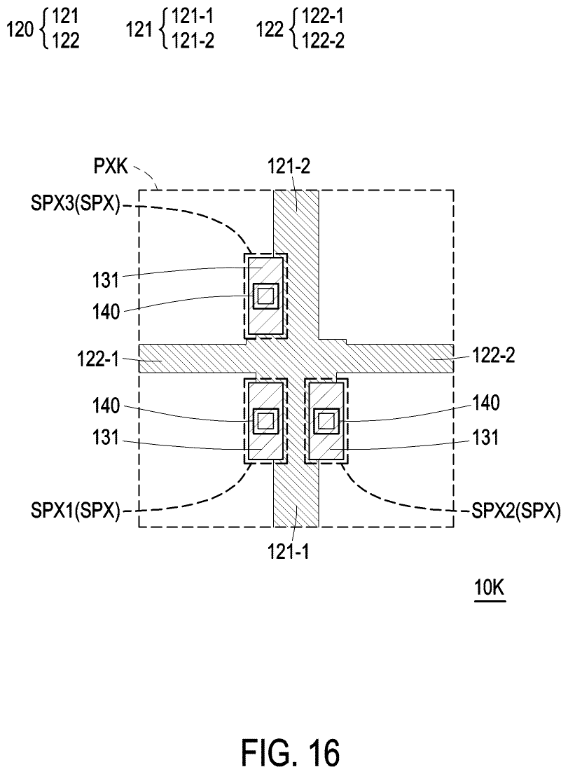

FIG. 16 is a schematic top view of the pixel structure of the display panel according to yet another embodiment of the present disclosure. The pixel structure PXK of the display panel 10K in FIG. 16 is similar to the pixel structure PXJ of the display panel 10J in FIG. 15. The difference between the two is: in the embodiment of FIG. 16, in the top view of the pixel structure PXK, the first pad 131 of the first sub-pixel structure SPX1 and the first pad 131 of the third sub-pixel structure SPX3 are located on the same side of the first common electrode portion 121.

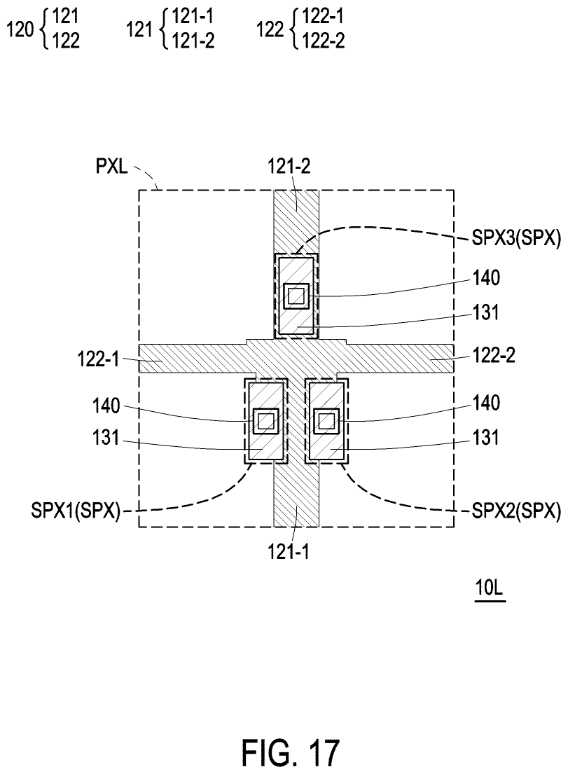

FIG. 17 is a schematic top view of the pixel structure of the display panel according to one embodiment of the present disclosure. The pixel structure PXL of the display panel 10L in FIG. 17 is similar to the pixel structure PXJ of the display panel 10J in FIG. 15. The difference between the two is: in the embodiment of FIG. 17, in the top view of the pixel structure PXJ, the first pad 131 of the third pixel electrode SPX3 is located on the second sub-portion 121-2 of the first common electrode portion 121.

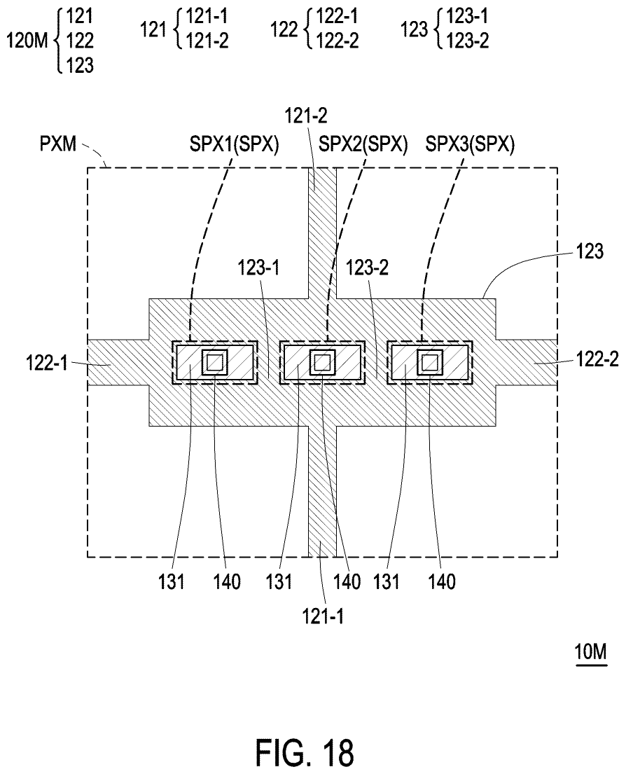

FIG. 18 is a schematic top view of the pixel structure of the display panel according to another embodiment of the present disclosure. The pixel structure PXM of the display panel 10M of FIG. 18 is similar to the pixel structure PXH of the display panel 10H of FIG. 13, the common electrode 120M of FIG. 18 also includes a first common electrode portion 121, a second common electrode portion 122 and a conductive portion 123, the difference between the two is that in the embodiment of FIG. 18, the pad group 130 of each of the sub-pixel structures SPX includes a first pad 131 and may not be include the second pad 132 in FIG. 13. In addition, in the embodiment of FIG. 18, the light-emitting element 140 of each of the sub-pixel structures SPX may be a vertical type light-emitting element.

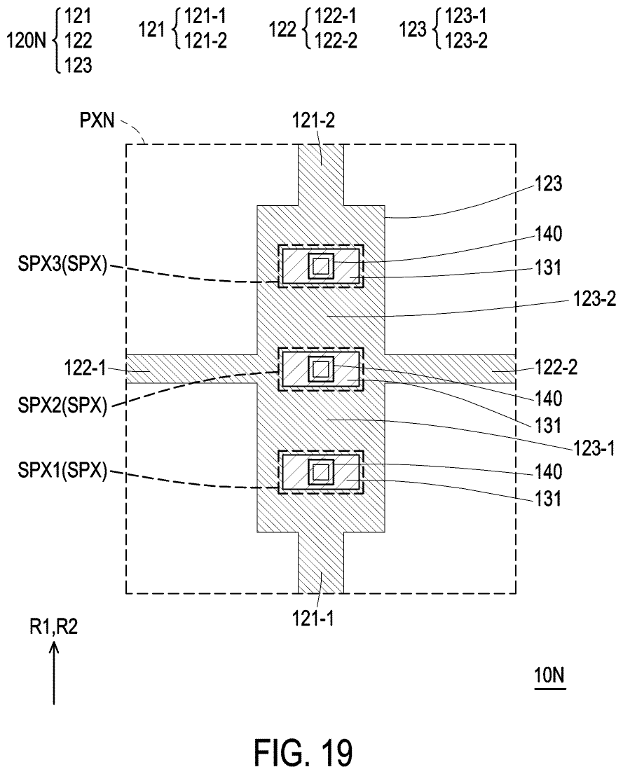

FIG. 19 is a schematic top view of the pixel structure of the display panel according to another embodiment of the present disclosure. The pixel structure PXN of the display panel 10N of FIG. 19 is similar to the pixel structure PXH of the display panel 10H of FIG. 14, the common electrode 120N in FIG. 19 also includes a first common electrode portion 121, a second common electrode portion 122 and a conductive portion 123, the difference between the two is: in the embodiment of FIG. 19, the pad group 130 of each of the sub-pixel structures SPX includes the first pad 131 but may not include the second pad 132 of FIG. 14. In addition, in the embodiment of FIG. 19, the light-emitting element 140 of each of the sub-pixel structures SPX may be a vertical type light-emitting element.

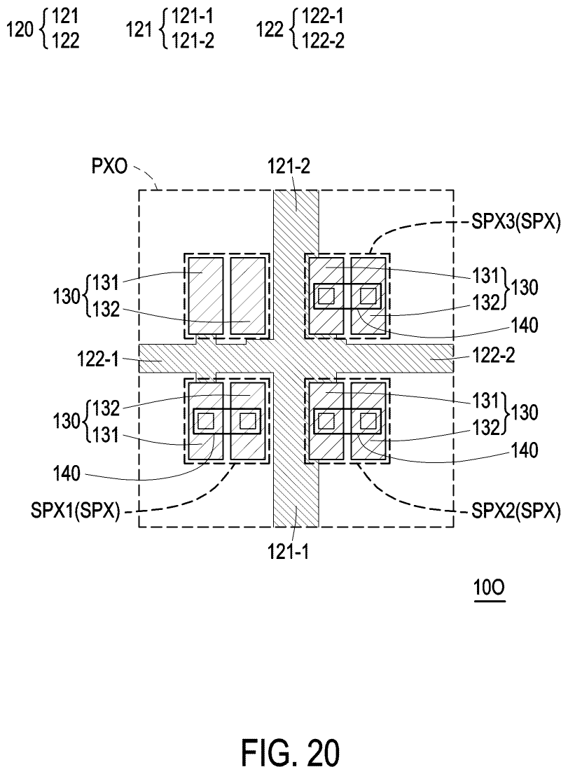

FIG. 20 is a schematic top view of the pixel structure of the display panel according to yet another embodiment of the present disclosure. The pixel structure PXO of the display panel 10O of FIG. 20 is similar to the pixel structure PX of the display panel 10 of FIG. 2, the difference between the two is that in the embodiment of FIG. 20, in addition to the pad groups 130 of the first sub-pixel structure SPX1, the second sub-pixel structure SPX2 and the third sub-pixel structure SPX3, the pixel structure PXO further includes another pad group 130 for repair. In some embodiments, in the top view of the pixel structure PXO, the other pad group 130 for repair and the pad group 130 of the first sub-pixel structure SPX1 may be located on opposite sides of the second common electrode portion 122 respectively, and the other pad group 130 for repair and the pad group 130 of the third sub-pixel structure SPX3 may be located on opposite sides of the first common electrode portion 121 respectively.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel structure comprising:
a common electrode comprising a first common electrode portion and a second common electrode portion crossing each other; and
sub-pixel structures, wherein each of the sub-pixel structures comprising:
a pad group, at least comprising a first pad; and
a light-emitting element, bonded to the pad group;
wherein the sub-pixel structures comprises a first sub-pixel structure, a second sub-pixel structure and a third sub-pixel structure;
in a top view of the pixel structure, the pad group of the first sub-pixel structure and the pad group of the second sub-pixel structure are separated by the first common electrode portion, and the pad group of the second sub-pixel structure and the pad group of the third sub-pixel structure are separated by the second common electrode portion.

2. The pixel structure according to claim 1, wherein a first direction is substantially parallel to the first common electrode portion, a second direction is substantially parallel to the second common electrode portion, and the pad group of each of the sub-pixel structures is disposed adjacent to the first common electrode portion and has a first size in the first direction, and the pad group of each of the sub-pixel structures is disposed adjacent to the second common electrode portion and has a second size in the second direction; a ratio of a sum of the first size and the second size of the first sub-pixel structure to a sum of the first size and the second size of the second sub-pixel structure is greater than 0.8 and less than 1.2.

3. The pixel structure according to claim 2, wherein a ratio of the sum of the first size and the second size of the second sub-pixel structure to a sum of the first size and the second size of the third sub-pixel structure is greater than 0.8 and less than 1.2.

4. The pixel structure according to claim 1, wherein a first direction is substantially parallel to the first common electrode portion, there is a gap between the pad group of the second sub-pixel structure and the pad group of the third sub-pixel structure, and a width of the gap in the first direction is greater than or equal to 5 μm.

5. The pixel structure according to claim 1, wherein the pad group of each of the sub-pixel structures further comprises a second pad that is structurally separated from the first pad; the first common electrode portion comprises a first sub-portion and a second sub-portion respectively located on opposite sides of the second common electrode portion; the first pad of the second sub-pixel structure has a long side and a short side adjacent to each other; in a top view of the pixel structure, the long side of the first pad of the second sub-pixel structure is adjacent to the first sub-portion of the first common electrode portion, and the first pad of the second sub-pixel structure separates the second pad of the second sub-pixel structure from the common electrode; the first pad of the third sub-pixel structure has a long side and a short side adjacent to each other; in the top view of the pixel structure, the long side of the first pad of the third sub-pixel structure is adjacent to the second sub-portion of the first common electrode portion, and the first pad of the third sub-pixel structure separates the second pad of the third sub-pixel structure from the common electrode.

6. The pixel structure according to claim 5, wherein the second common electrode portion comprises a first sub-portion and a second sub-portion respectively located on opposite sides of the first common electrode portion; the first pad of the first sub-pixel structure has a long side and a short side adjacent to each other; in the top view of the pixel structure, the short side of the first pad of the first sub-pixel structure is adjacent to the first sub-portion of the second common electrode portion, and the short side of the first pad of the third sub-pixel structure is adjacent to the second sub-portion of the second common electrode portion.

7. The pixel structure according to claim 5, wherein the second common electrode portion comprises a first sub-portion and a second sub-portion respectively located on opposite sides of the first common electrode portion; the first pad of the first sub-pixel structure has a long side and a short side adjacent to each other; in the top view of the pixel structure, the short side of the first pad of the first sub-pixel structure is adjacent to the first sub-portion of the second common electrode portion, and the short side of the first pad of the third sub-pixel structure is adjacent to the first sub-portion of the second common electrode portion.

8. The pixel structure according to claim 5, wherein the first pad of the first sub-pixel structure has a long side and a short side adjacent to each other; in the top view of the pixel structure, the long side of the first pad of the first sub-pixel structure is adjacent to the first sub-portion of the first common electrode portion, and the first pad of the first sub-pixel structure separates the second pad of the first sub-pixel structure from the first common electrode portion.

9. A pixel structure comprising:
a common electrode comprising a conductive portion, wherein the conductive portion comprises a first sub-portion and a second sub-portion outside the first sub-portion; and
sub-pixel structures, wherein each of the sub-pixel structures comprising:
a pad group, at least comprising a first pad; and
a light-emitting element, bonded to the pad group;
the sub-pixel structures comprise a first sub-pixel structure, a second sub-pixel structure and a third sub-pixel structure respectively arranged in a straight direction;
in a top view of the pixel structure, the pad group of the first sub-pixel structure and the pad group of the second sub-pixel structure are separated by the first sub-portion of the conductive portion of the common electrode, and the pad group of the second sub-pixel structure and the pad group of the third sub-pixel structure are separated by the second sub-portion of the conductive portion of the common electrode.

10. The pixel structure according to claim 9, wherein the pad group of each of the sub-pixel structures further comprises a second pad that is structurally separated from the first pad; the conductive portion of the common electrode has a first opening, a second opening and a third opening, and the first sub-portion of the conductive portion is located between the first opening and the second opening, and the second sub-portion of the conductive portion is located between the second opening and the third opening; in the top view of the pixel structure, the second pad of the first sub-pixel structure, the second pad of the second sub-pixel structure and the second pad of the third sub-pixel structure are respectively located at the first opening, the second opening and the third opening.

11. The pixel structure according to claim 10, wherein an arrangement direction of the first pad and the second pad of each of the sub-pixel structures is staggered with an arrangement direction of the first opening, the second opening and the third opening.

12. The pixel structure according to claim 10, wherein an arrangement direction of the first pad and the second pad of each of the sub-pixel structures is consistent with an arrangement direction of the first opening, the second opening and the third opening.
